(19) United States
(12) Patent Application Publication
(10) Pub. No.: US 2009/0102579 A1
(43) Pub. Date: Apr. 23, 2009

(54) FREQUENCY DIVISION COUPLING CIRCUIT AND APPLICATIONS THEREOF

(75) Inventor: AHMADREZA (REZA) ROFOUGARAN, Newport Coast, CA (US)

Correspondence Address: GARLICK HARRISON & MARKISON, P.O. BOX 160727, AUSTIN, TX, 78716-0727, US

(73) Assignee: BROADCOM CORPORATION, Irvine, CA (US)

(21) Appl. No.: 12/188,073

(22) Filed: Aug. 7, 2008

Related U.S. Application Data
(63) Continuation-in-part of application No. 11/648,826, filed on Dec. 29, 2006.
Application No. 11/648,826 is a continuation-in-part of application No. 11/691,460, filed on Mar. 26, 2007.

(51) Int. Cl. H03H 7/46; H03H 7/38

(52) U.S. Cl. 333/129; 333/132

(57) ABSTRACT

A frequency division coupling circuit includes first and second trace segments and first and second segregation modules. The first and second trace segments function to convey a first signal in a first frequency range and the first trace segment conveys a second signal in a second frequency range. A first port of the first segregation module transmits or receives the first signal to or from the first and second trace segments and a second port of the first segregation module transmits or receives the second signal to or from the first trace segment. A first port of the second segregation module transmits or receives the first signal to or from the first and second trace segments and a second port of the second segregation module transmits or receives the second signal to or from the first trace segment.

This patent application is claiming priority under 35 USC § 120 as a continuation in part patent application of co-pending patent application entitled INTEGRATED CIRCUIT ANTENNA STRUCTURE, having a filing date of Dec. 29, 2006, and a Ser. No. 11/648,826 and of co-pending patent application entitled VERY HIGH FREQUENCY DIELECTRIC SUBSTRATE WAVE GUIDE, having a filing date of Mar. 26, 2007, and a Ser. No. 11/691,460.

### STATEMENT REGARDING FEDERALLY SPONSORED RESEARCH OR DEVELOPMENT

NOT APPLICABLE

### INCORPORATION-BY-REFERENCE OF MATERIAL SUBMITTED ON A COMPACT DISC

NOT APPLICABLE

### BACKGROUND OF THE INVENTION

1. Technical Field of the Invention

This invention relates generally to wireless communication and more particularly to coupling on and/or to/from integrated circuits.

2. Description of Related Art

Communication systems are known to support wireless and wire lined communications between wireless and/or wire lined communication devices. Such communication systems range from national and/or international cellular telephone systems to the Internet to point-to-point in-home wireless networks to radio frequency identification (RFID) systems. Each type of communication system is constructed, and hence operates, in accordance with one or more communication standards. For instance, wireless communication systems may operate in accordance with one or more standards including, but not limited to, RFID, IEEE 802.11, Bluetooth, advanced mobile phone services (AMPS), digital AMPS, global system for mobile communications (GSM), code division multiple access (CDMA), local multi-point distribution systems (LMDS), multi-channel-multi-point distribution systems (MMDS), and/or variations thereof.

Depending on the type of wireless communication system, a wireless communication device, such as a cellular telephone, two-way radio, personal digital assistant (PDA), personal computer (PC), laptop computer, home entertainment equipment, RFID reader, RFID tag, et cetera communicates directly or indirectly with other wireless communication devices. For direct communications (also known as point-to-point communications), the participating wireless communication devices tune their receivers and transmitters to the same channel or channels (e.g., one of the plurality of radio frequency (RF) carriers of the wireless communication system) and communicate over that channel(s). For indirect wireless communications, each wireless communication device communicates directly with an associated base station (e.g., for cellular services) and/or an associated access point (e.g., for an in-home or in-building wireless network) via an assigned channel. To complete a communication connection between the wireless communication devices, the associated base stations and/or associated access points communicate with each other directly, via a system controller, via the public switch telephone network, via the Internet, and/or via some other wide area network.

For each wireless communication device to participate in wireless communications, it includes a built-in radio transceiver (i.e., receiver and transmitter) or is coupled to an associated radio transceiver (e.g., a station for in-home and/or in-building wireless communication networks, RF modem, etc.). As is known, the receiver is coupled to the antenna and includes a low noise amplifier, one or more intermediate frequency stages, a filtering stage, and a data recovery stage. The low noise amplifier receives inbound RF signals via the antenna and amplifies then. The one or more intermediate frequency stages mix the amplified RF signals with one or more local oscillations to convert the amplified RF signal into baseband signals or intermediate frequency (IF) signals. The filtering stage filters the baseband signals or the IF signals to attenuate unwanted out of band signals to produce filtered signals. The data recovery stage recovers raw data from the filtered signals in accordance with the particular wireless communication standard.

As is also known, the transmitter includes a data modulation stage, one or more intermediate frequency stages, and a power amplifier. The data modulation stage converts raw data into baseband signals in accordance with a particular wireless communication standard. The one or more intermediate frequency stages mix the baseband signals with one or more local oscillations to produce RF signals. The power amplifier amplifies the RF signals prior to transmission via an antenna.

In most applications, radio transceivers are implemented in one or more integrated circuits (ICs), which are inter-coupled via traces on a printed circuit board (PCB). The radio transceivers operate within licensed or unlicensed frequency spectrums. For example, wireless local area network (WLAN) transceivers communicate data within the unlicensed Industrial, Scientific, and Medical (ISM) frequency spectrum of 900 MHz, 2.4 GHz, and 5 GHz. While the ISM frequency spectrum is unlicensed there are restrictions on power, modulation techniques, and antenna gain.

As IC fabrication technology continues to advance, ICs will become smaller and smaller with more and more transistors. While this advancement allows for reduction in size of electronic devices, it does present a design challenge of providing and receiving signals, data, clock signals, operational instructions, etc., to and from a plurality of ICs of the device and wells as for internal connections of an IC. Currently, this is addressed by improvements in IC packaging and multiple layer PCBs. For example, ICs may include a ball-grid array of 100-200 pins in a small space (e.g., 2 to 20 millimeters by 2 to 20 millimeters). A multiple layer PCB includes traces for each one of the pins of the IC to route to at least one other component on the PCB. Clearly, advancements in communication between ICs and within an IC are needed to adequately support the forth-coming improvements in IC fabrication.

Therefore, a need exists for intra-IC and/or inter-IC frequency division communications and applications thereof.

### BRIEF SUMMARY OF THE INVENTION

The present invention is directed to apparatus and methods of operation that are further described in the following Brief Description of the Drawings, the Detailed Description of the Invention, and the claims. Other features and advantages of the present invention will become apparent from the following detailed description of the invention made with reference to the accompanying drawings.

### BRIEF DESCRIPTION OF THE SEVERAL VIEWS OF THE DRAWING(S)

FIG. 1 is a schematic block diagram of an embodiment of an integrated circuit (IC) in accordance with the present invention;

FIG. 2 is a schematic block diagram of an embodiment of a frequency division coupling module in accordance with the present invention;

FIG. 3 is a schematic block diagram of another embodiment of a frequency division coupling module in accordance with the present invention;

FIG. 4 is a schematic block diagram of another embodiment of a frequency division coupling module in accordance with the present invention;

FIG. 5 is a perspective diagram of another embodiment of a frequency division coupling module in accordance with the present invention;

FIG. 6 is a schematic block diagram of another embodiment of an IC in accordance with the present invention;

FIG. 7 is a schematic block diagram of another embodiment of a frequency division coupling module in accordance with the present invention;

FIG. 8 is a perspective diagram of another embodiment of a frequency division coupling module in accordance with the present invention;

FIG. 9 is a perspective diagram of another embodiment of an IC in accordance with the present invention;

FIG. 10 is a perspective diagram of another embodiment of an IC in accordance with the present invention;

FIG. 11 is a schematic block diagram of an embodiment of a frequency division coupling module connected to two circuit blocks in accordance with the present invention; and

FIG. 12 is an isometric view of an embodiment of a frequency division coupling module in accordance with the present invention.

### DETAILED DESCRIPTION OF THE INVENTION

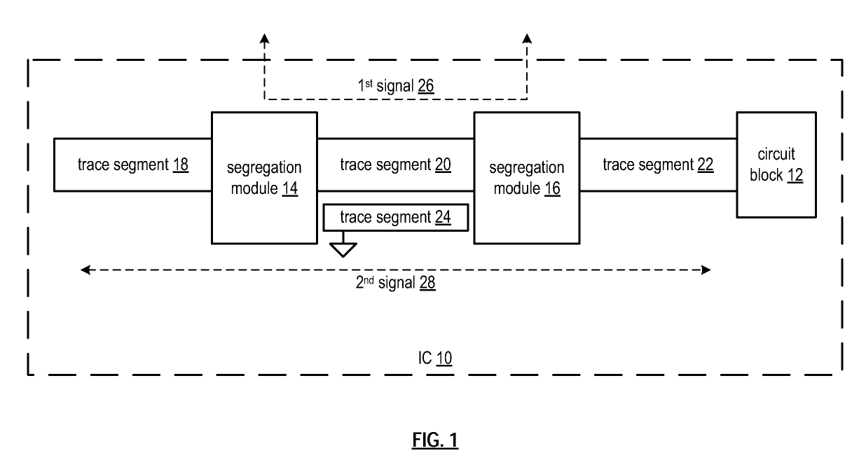

FIG. 1 is a schematic block diagram of an embodiment of an integrated circuit (IC) 10 that includes a frequency division coupling module, a circuit block 12, and trace segments 18 and 22. The frequency division coupling module includes a plurality of segregation modules 14-16, and a plurality of trace segments 20 and 24. The circuit block 12 may be a memory block, a digital circuit, an analog circuit, a logic circuit, a processing circuit, a combination thereof, or any other type of circuit that receives and/or transmits signals. The IC 10 may be implemented using any one of a plurality of IC fabrication techniques including, but not limited to, CMOS (complimentary metal oxide semiconductor), bi-CMOS, Gallium Arsenide, Silicon Germanium, etc. having one or more metal layers.

In this embodiment, the trace segments 20 and 24 (e.g., a metal trace on one or more metal layers of the IC 10) provide a transmission line between the segregation modules 14-16 to support a first signal 26. In addition, a series connection of the trace segments 18-22 and the segregation modules 14-16 provides coupling of a second signal 28 to the circuit block 12. The first signal 26 is in a first frequency range and the second signal 28 is within a second frequency range, wherein frequencies of the second frequency range are less than frequencies of the first frequency range. Note that once the length of a trace is 1/10 or greater the wavelength of the signal it carries, the trace exhibits transmission line characteristics, which, as described herein, can be advantageously used for concurrently carrying multiple signals via the same trace with little or no interference between the signals.

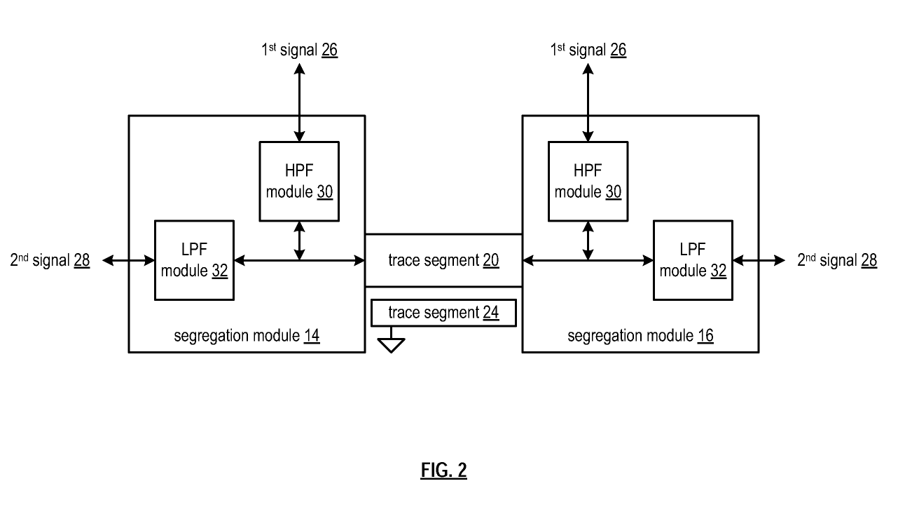

For example, the segregation modules 14-16 may be coupled to provide the first signal 26 to other circuit blocks (not shown) and the second signal 28 to the circuit block 12. In this example, the segregation modules 14-16 convey the first signal 26 therebetween via the transmission line produced by the trace segments 20 and 24, which are proximally located. In addition, the segregation modules 14-16 convey the second signal 28 via the trace segments 20 and 22 to the circuit block 12, which can be concurrently or in a time division manner with respect to the first signal 26. The segregation modules 14-16 include circuitry to segregate the first signal 26 from the second signal 28 such that the signals 26 and 28 have little or no cross-signal interference. For instance, if the first frequency range is above 60 GHz and the second frequency range is below 6 GHz, then the circuitry of the segregation modules 14-16 substantially blocks the first signal 26, which is in the first frequency range, from being present on trace segments 18 and 22 and passes the second signal 28, which is in the second frequency range. Various embodiments of the segregation modules 14-16 will be described with reference to FIGS. 2-5.

While the embodiment of FIG. 1 shows the frequency division coupling module on the IC 10 to provide coupling of signals to one or more circuit blocks, the frequency division coupling module may be implemented on a printed circuit board (PCB) to provide coupling between two or more ICs. Further, the frequency division coupling circuit may be used to provide coupling between circuit blocks on an IC and to provide coupling between the IC and another IC.

As discussed, trace segment 24 in combination with trace segment 20 provides a transmission line for conveying the first signal 26. In one implementation, trace segment 24 is a ground plane such that the transmission line is a microstrip transmission line. In another implementation, trace segment 24 is a power supply return line and trace segment 20 may be a power supply line or a data line. In yet another implementation, trace segment 24 may be a second signal line carrying another signal in the second frequency range.

FIG. 2 is a schematic block diagram of an embodiment of a frequency division coupling module that includes the segregation module 14-16 and traces segments 20 and 24. The segregation modules 14-16 include three ports: A first port is coupled to a high pass filter module 30 that passes, substantially unattenuated, the first signal 26 to the transmission line via the third port and substantially blocks the second signal 28 from being present at the first port; and a second port is coupled to a low pass filter module 32 that passes, substantially unattenuated, the second signal 28 to trace segment 20 via the third port and substantially blocks the first signal 26 from being present at the second port.

The corner frequencies and the attenuation rate of the high pass and low pass filters is dependent upon the first frequency range and the second frequency range. The further the ranges are about, the less attenuation rate each filter 30 and 32 needs and establishment of the corner frequency can be set to ensure minimal attenuation of the desired signals. If, however, the ranges are relatively close, the attenuate rates of the filters 30 and 32 will have to be fairly substantial and the corner frequency may be established at the 3 dB point. In the latter example, the segregation modules 14-16 may further include notch filters coupled to the first and second ports to further attenuate the unwanted signal at the respective ports.

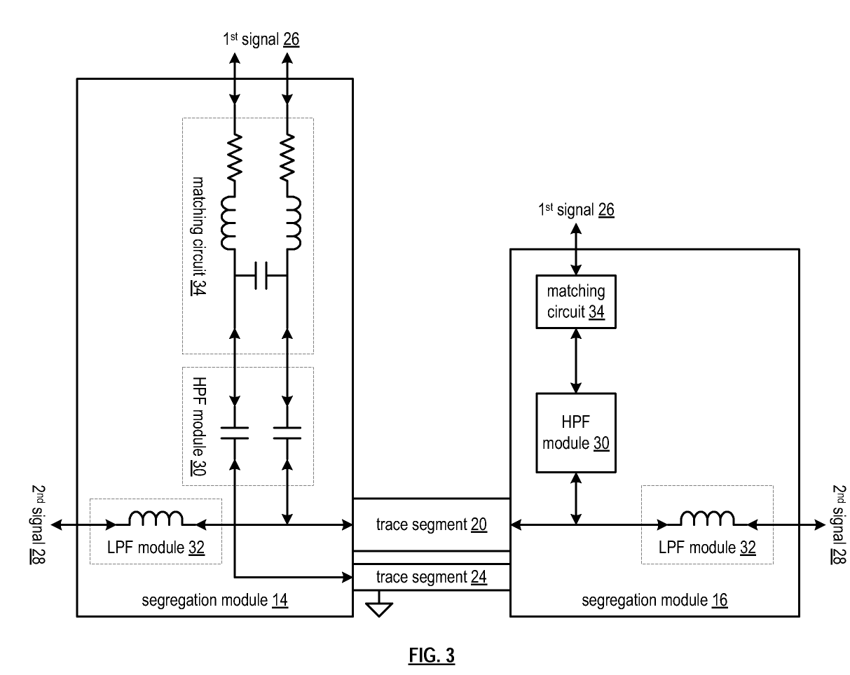

FIG. 3 is a schematic block diagram of another embodiment of a frequency division coupling module that includes the segregation module 14-16 and traces segments 20 and 24. The segregation modules 14-16 include a high pass filter module 30, a low pass filter module 32, and matching circuit 34. In this embodiment, the low pass filter module 32 may be implemented via one or more inductors and the high pass filter module 30 may be implemented by one or more capacitors. Note that the first signal 26 may be a single-ended signal or a differential signal.

The matching circuit 34 provides an impedance matching such that, in the first frequency range, the input/output impedance of the segregation modules 14 and 16 substantially match the impedance of the transmission line (i.e., trace segments 20 and 24). An embodiment of the matching circuit module 34 may include one or more inductors, one or more capacitors, and/or one or more resistors. As an example, the impedance of the matching circuit is established (e.g., 5-200 Ohms) such that input impedance of a source of the first signal (e.g., circuit block 12) and output impedance of a destination of the first signal (e.g., another circuit block) substantially match impedance of the transmission line (e.g., 5-200 Ohms in the first frequency range). Note that in the first frequency range, the impedance of the low pass filter module 32 is very large in comparison to the impedance of the high pass filter 30 and the matching circuit module 34 such that, for practical purposes, it can be ignored in determining the impedance of the segregation module 14-16 in this frequency range.

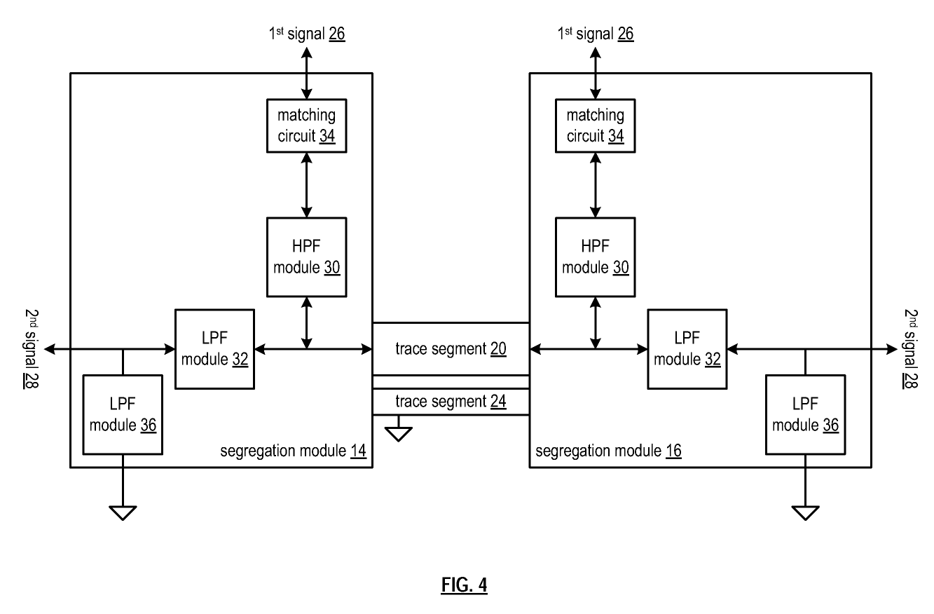

FIG. 4 is a schematic block diagram of another embodiment of a frequency division coupling module that includes the segregation module 14-16 and traces segments 20 and 24. The segregation modules 14-16 include a high pass filter module 30, a low pass filter module 32, the matching circuit 34, and a second low pass filter 36. In this embodiment, the second low pass filter module 36 has a corner frequency greater than the second frequency range to further attenuate unwanted signal components of the first signal 26 may be my passed by the low pass filter module 32. Such further low pass filtering may be needed when the different between the first and second frequency ranges is less than a factor of 100.

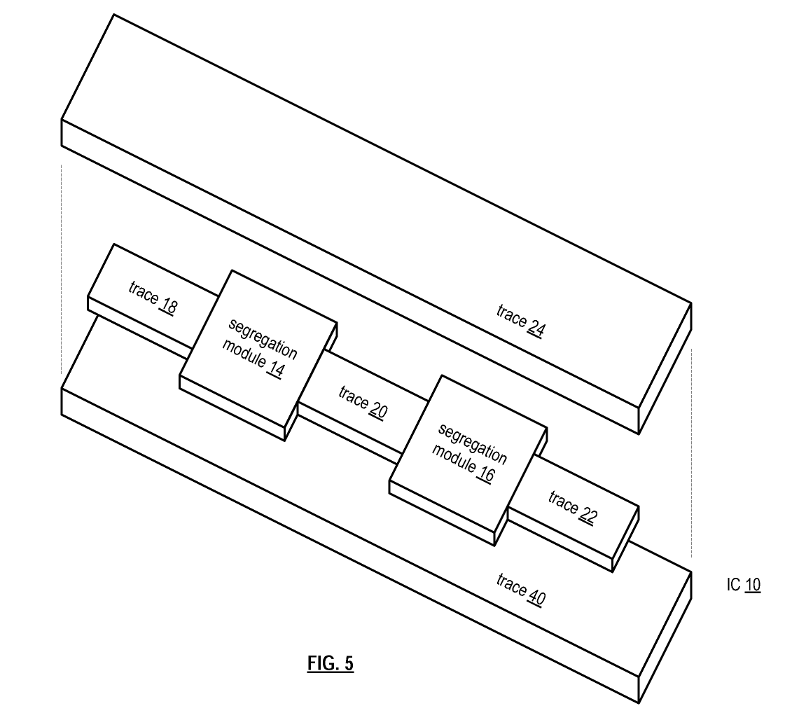

FIG. 5 is a perspective diagram of another embodiment of a frequency division coupling module that includes the segregation module 14-16 and traces segments 20, 24, and 40. The segregation modules 14 and 16 are coupled to trace segments 18 and 22, respectively. In this embodiment, the trace segments 24 and 40 are ground planes where the segregation modules 14-16 and trace segment 20 are between the trace segments 24 and 40 to provide a stripline transmission line.

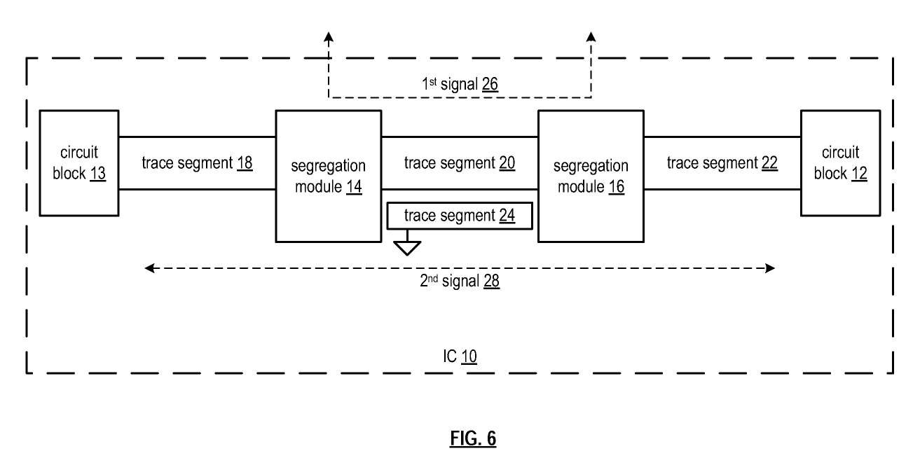

FIG. 6 is a schematic block diagram of another embodiment of an IC 10 that includes a frequency division coupling module, circuit block 12, another circuit block 13, and trace segments 18 and 22. The frequency division coupling module includes a plurality of segregation modules 14-16, and a plurality of trace segments 20 and 24. The circuit blocks 12 and 13 may be a memory block, a digital circuit, an analog circuit, a logic circuit, a processing circuit, a combination thereof, or any other type of circuit that receives and/or transmits signals.

In this embodiment, the trace segments 20 and 24 (e.g., a metal trace on one or more metal layers of the IC 10) provide a transmission line between the segregation modules 14-16 to support a first signal 26. In addition, a series connection of the trace segments 18-22 and the segregation modules 14-16 provides coupling of a second signal 28 between the circuit blocks 12 and 13. The first signal 26 may be conveyed between the circuit blocks 12 and 13, between different circuit blocks (not shown), or between one of the circuit blocks 12 and 13 and a different circuit block (not shown).

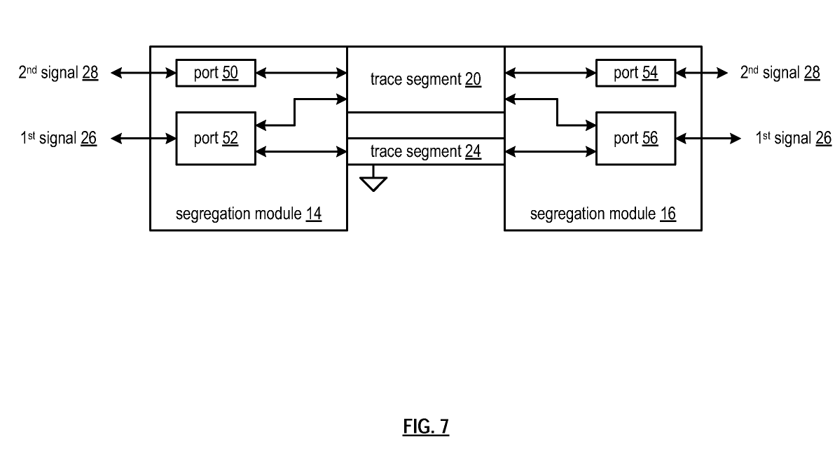

FIG. 7 is a schematic block diagram of another embodiment of a frequency division coupling module that includes trace segments 20 and 24 and segregation modules 14 and 16. In this embodiment, trace segment 24 is proximal and parallel to trace segment 24 such that, in combination, the trace segments 20 and 24 function to convey a first signal 26 in a first frequency range. In addition, trace segment 20 conveys a second signal 28 in a second frequency range, where frequencies of the second frequency range are less than frequencies of the first frequency range.

The first segregation module 14 includes ports 50 and 52 and second segregation module 16 includes ports 54 and 56. As shown port 52 of the first segregation module 14 transmits or receives the first signal 26 to or from trace segments 20 and 24 and a second port 50 of the first segregation module 14 transmits or receives the second signal 28 to or from trace segment 20. The first port 56 of the second segregation module 16 transmits or receives the first signal 26 to or from the trace segments 20 and 24 and the second port 54 of the second segregation module 16 transmits or receives the second signal 28 to or from trace segment 20.

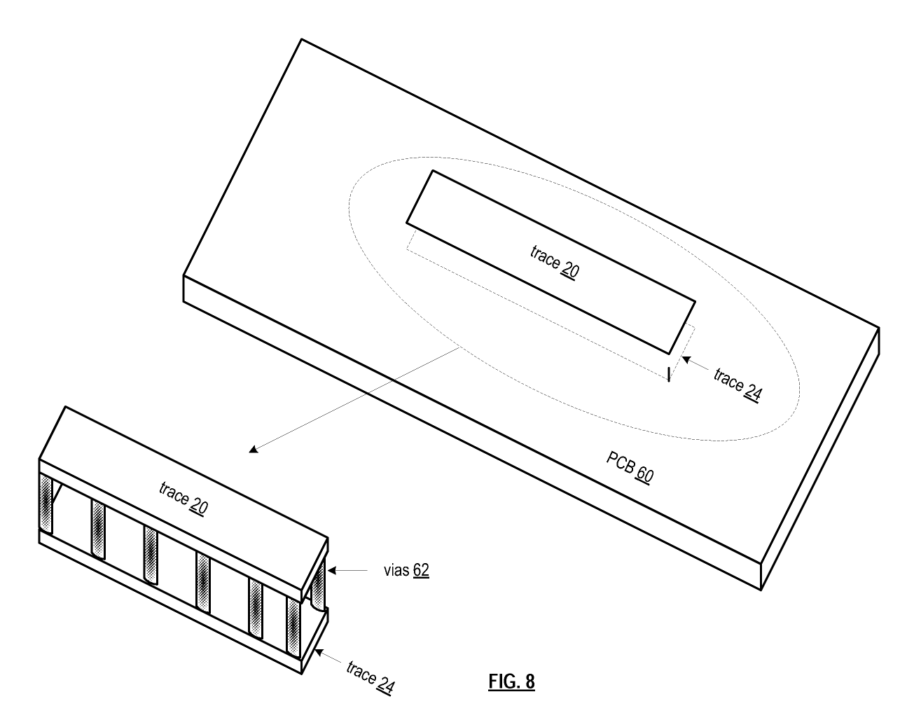

FIG. 8 is a perspective diagram of another embodiment of a frequency division coupling module implemented on a printed circuit board (PCB) 60. In this embodiment, the frequency division coupling module may be used to convey multiple signals between ICs (not shown) or other circuit blocks (not shown) that are supported by the PCB 60. Further, the frequency division coupling module includes trace segments 20 and 24, segregation modules 14 and 16, and a plurality of vias. The plurality of vias is coupled to the trace segments 20 and 24 to provide a waveguide for the first signal 26.

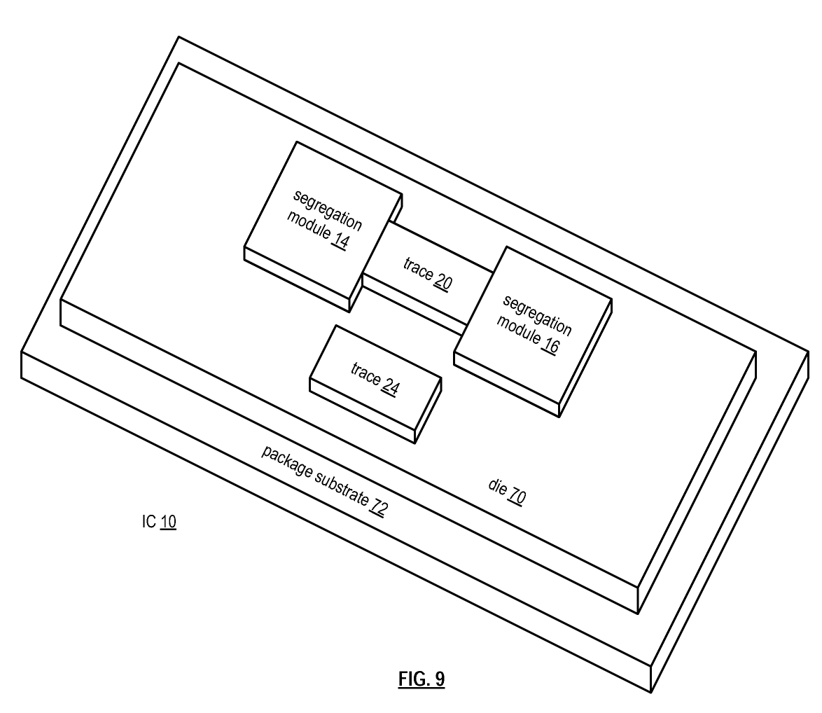

FIG. 9 is a perspective diagram of another embodiment of an IC 10 that includes a die 70 and a package substrate 72. In this embodiment, the package substrate 72 supports the die and the die 70 supports the frequency division coupling module (i.e., the trace segments 20 and 24 and the segregation modules 14 and 16). Accordingly, the frequency division coupling module is used for inter-chip communications of the first and second signals 26 and 28.

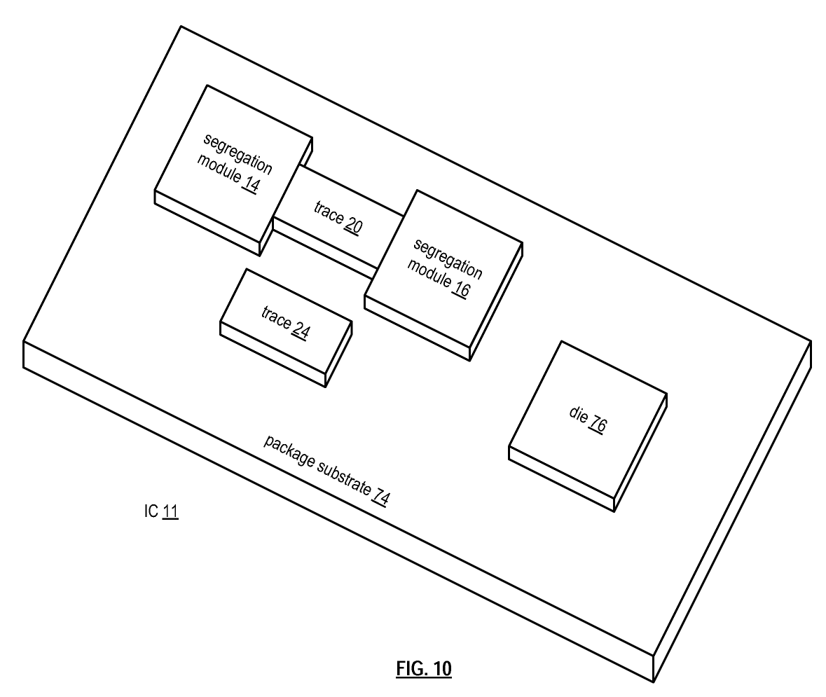

FIG. 10 is a perspective diagram of another embodiment of an IC 10 that includes a die 76 and a package substrate 72. In this embodiment, the package substrate 72 supports the die 76 and the frequency division coupling module (i.e., the trace segments 20 and 24 and the segregation modules 14 and 16). As such, the frequency division coupling module is used for inter-chip or intra-chip communications of the first and second signals 26 and 28 between the die 76 and another IC or between the die 76 and another die (not shown) on the substrate 74.

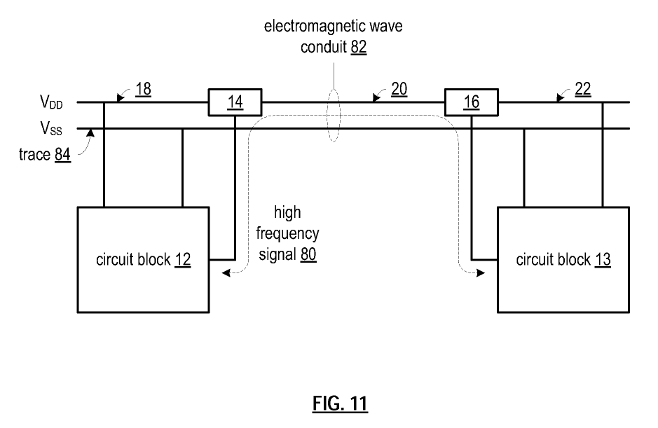

FIG. 11 is a schematic block diagram of an embodiment of a frequency division coupling module (i.e., segregation modules 14 and 16 and traces 20 and 84) connected to two circuit blocks 12 and 13. Each of the segregation modules 14 and 16 include three ports. A first port of the segregation module 14 or 16 supports a high frequency signal 80, a second port of the segregation module 14 or 16 supports a power connection (e.g., V_{DD} or V_{SS}), and a third port of the segregation module 14 or 16 supports the high frequency signal 80 and the power connection (e.g., V_{DD} or V_{SS}). Trace segments 20 and 84 provide an electromagnetic wave conduit 82 (e.g., a transmission line or a waveguide) for the high frequency signal, trace segment 20 supports the power connection (e.g., V_{DD}), and trace segment 84 supports the other power connection (e.g., V_{SS}).

In this embodiment, the segregation modules 14 and 16, via the traces 18-22 and 84, provide coupling of the power supply (V_{DD}), the power supply return (V_{SS}) and the high frequency signals 80 for the circuit blocks 12 and 13. In this manner, the power supply traces are used to support the high frequency signal such that additional traces are not needed.

As may be used herein, the terms “substantially” and “approximately” provides an industry-accepted tolerance for its corresponding term and/or relativity between items. Such an industry-accepted tolerance ranges from less than one percent to fifty percent and corresponds to, but is not limited to, component values, integrated circuit process variations, temperature variations, rise and fall times, and/or thermal noise. Such relativity between items ranges from a difference of a few percent to magnitude differences. As may also be used herein, the term(s) “coupled to” and/or “coupling” and/or includes direct coupling between items and/or indirect coupling between items via an intervening item (e.g., an item includes, but is not limited to, a component, an element, a circuit, and/or a module) where, for indirect coupling, the intervening item does not modify the information of a signal but may adjust its current level, voltage level, and/or power level. As may further be used herein, inferred coupling (i.e., where one element is coupled to another element by inference) includes direct and indirect coupling between two items in the same manner as “coupled to”. As may even further be used herein, the term “operable to” indicates that an item includes one or more of power connections, input(s), output(s), etc., to perform one or more its corresponding functions and may further include inferred coupling to one or more other items. As may still further be used herein, the term “associated with”, includes direct and/or indirect coupling of separate items and/or one item being embedded within another item. As may be used herein, the term “compares favorably”, indicates that a comparison between two or more items, signals, etc., provides a desired relationship. For example, when the desired relationship is that signal 1 has a greater magnitude than signal 2, a favorable comparison may be achieved when the magnitude of signal 1 is greater than that of signal 2 or when the magnitude of signal 2 is less than that of signal 1.

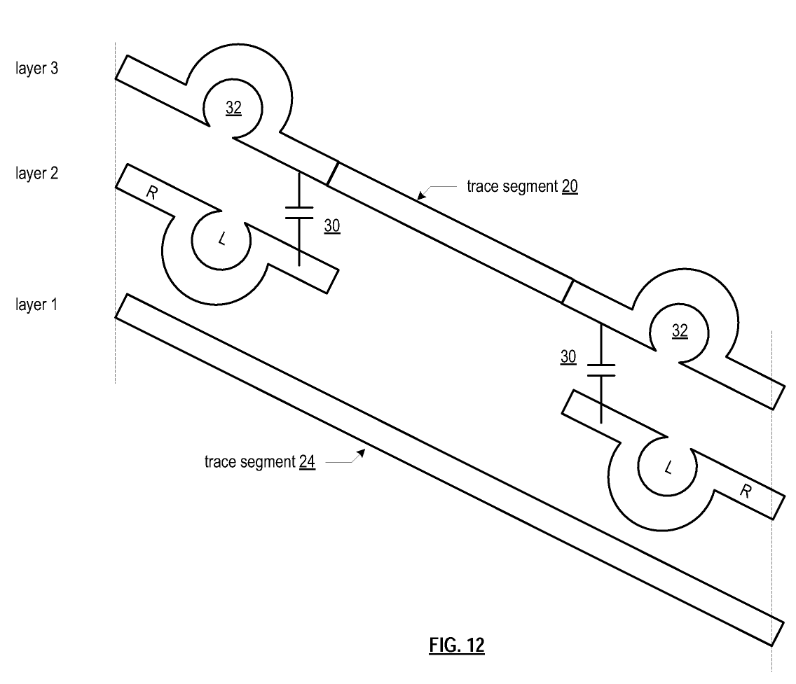

FIG. 12 is an isometric view of an embodiment of a frequency division coupling module implemented on three layers of a die 70, of a package substrate 72, or of a printed circuit board 60. As shown, trace 24 is on the bottom layer of the three layers. On the next layer is the high frequency coupling module 30, which is implemented via capacitive coupling between the trace of the HPF module 30 and traces of the LPF module 32. Note that the dielectric between the traces of the HPF and LPF modules 30 and 32 may be selected to provide the desired capacitance. Further note that the thickness of the dielectric between the traces of the HPF and LPF modules 30 and 32 may be selected to provide the desired capacitance. Still further note that the thickness and/or overlay of the traces of the HPF and LPF modules 30 and 32 may be selected to provide the desired capacitance.

Also on the next layer is the matching circuit 34, which includes an inductor (L) and resistance (R) of the trace. Note that the resistance may be selected based on the dimensions of the trace. Further, a resistance may be added in series with the trace to provide the desired resistance. The inductor may be implemented by a single turn coil, a spiral coil, or other coil configuration to provide the desired inductance.

The LPF module 32 and the trace segment 20 are implemented on the top layer. The LPF module 32 may be implemented via an inductor that is a single turn coil, a spiral coil, or other coil configuration to provide the desired inductance. In such an implementation, minimal board or die space is needed to couple two signals to a circuit block.

The present invention has also been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claimed invention.

The present invention has been described above with the aid of functional building blocks illustrating the performance of certain significant functions. The boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality. To the extent used, the flow diagram block boundaries and sequence could have been defined otherwise and still perform the certain significant functionality. Such alternate definitions of both functional building blocks and flow diagram blocks and sequences are thus within the scope and spirit of the claimed invention. One of average skill in the art will also recognize that the functional building blocks, and other illustrative blocks, modules and components herein, can be implemented as illustrated or by discrete components, application specific integrated circuits, processors executing appropriate software and the like or any combination thereof.

What is claimed is:

1. An integrated circuit (IC) comprises:
a first trace segment;
a second trace segment;
a third trace segment proximal to the first trace segment, wherein, within a first frequency range, the first and third trace segments provide a transmission line;
a first segregation module coupled between the first and second trace segments, wherein the first segregation module segregates a first signal in the first frequency range from a second signal within a second frequency range, wherein frequencies of the second frequency range are less than frequencies of the first frequency range;
a circuit block; and
a second segregation module coupled between the second trace segment and the circuit block, wherein the second segregation module segregates the first signal from the second signal, wherein a series connection of the first and second trace segments and the first and second segregation modules provides coupling of the second signal to the circuit block, and wherein the first signal is conveyed via the transmission line.

2. The IC of claim 1, wherein each of the first and second segregation modules comprises:
a high pass filter module coupled to pass, substantially unattenuated, the first signal to the transmission line; and
a low pass filter module coupled to pass, substantially unattenuated, the second signal to the first or second trace section and to substantially block the first signal.

3. The IC of claim 1, wherein each of the first and second segregation modules comprises:
a high pass filter module coupled to pass, substantially unattenuated, the first signal to the transmission line;
a low pass filter module coupled to pass, substantially unattenuated, the second signal to the first or second trace section and to substantially block the first signal; and
a matching circuit module coupled to the high pass filter module, wherein the matching circuit module provides an impedance such that input impedance of a source of the first signal and output impedance of a destination of the first signal substantially match impedance of the transmission line.

4. The IC of claim 1, wherein each of the first and second segregation modules comprises:
a high pass filter module coupled to pass, substantially unattenuated, the first signal to the transmission line;
a low pass filter module coupled to pass, substantially unattenuated, the second signal to the first or second trace section and to substantially block the first signal;
a matching circuit module coupled to the high pass filter module, wherein the matching circuit module provides an impedance such that input impedance of a source of the first signal and output impedance of a destination of the first signal substantially match impedance of the transmission line; and
a second low pass filter coupled to the low pass filter, wherein the second low pass filter has a corner frequency greater than the second frequency range.

5. The IC of claim 1, wherein the third trace segment comprises at least one of:
a ground plane to provide such that the transmission line is a microstrip transmission line;
a power supply return line; and
a second signal line carrying another signal in the second frequency range.

6. The IC of claim 1 further comprises:
a fourth trace segment, wherein the third and fourth trace segments are ground planes and wherein the first trace segment is between the third and fourth trace segments to provide a stripline transmission line.

7. The IC of claim 1 further comprises:
a fourth trace segment coupled to the second segregation module; and
a second circuit block, wherein a series connection of the first, second, and fourth trace segments and the first and second segregation modules provides coupling of the second signal between the circuit block and the second circuit block.

8. A frequency division coupling circuit comprises:
a first trace segment;
a second trace segment proximal and parallel to the first trace segment, wherein, in combination, the first and second trace segments function to convey a first signal in a first frequency range, and wherein the first trace segment conveys a second signal in a second frequency range, wherein frequencies of the second frequency range are less than frequencies of the first frequency range;
a first segregation module coupled to one end of the first and second trace segments, wherein a first port of the first segregation module transmits or receives the first signal to or from the first and second trace segments and a second port of the first segregation module transmits or receives the second signal to or from the first trace segment; and
a second segregation module coupled to another end of the first and second trace segments, wherein a first port of the second segregation module transmits or receives the first signal to or from the first and second trace segments and a second port of the second segregation module transmits or receives the second signal to or from the first trace segment.

9. The frequency division coupling circuit of claim 8 further comprises:
a printed circuit board (PCB) substrate, wherein the first trace segment is on one layer of the PCB substrate and the second trace segment is on another layer of the PCB substrate; and
a plurality of vias coupled to the first and second trace segments to provide a waveguide for the first signal.

10. The frequency division coupling circuit of claim 8 further comprises:
a die, wherein the first and second trace segments and the first and second segregation modules are on the die; and
an integrated circuit (IC) package substrate that supports the die.

11. The frequency division coupling circuit of claim 8 further comprises:
a die; and
an integrated circuit (IC) package substrate that supports the die, wherein the first and second trace segments and the first and second segregation modules are on the IC package substrate.

12. The frequency division coupling circuit of claim 8, wherein each of the first and second segregation modules comprises:
a high pass filter module coupled to first port; and
a low pass filter module coupled to second port.

13. The frequency division coupling circuit of claim 8, wherein each of the first and second segregation modules comprises:
a high pass filter module coupled to first port;
a low pass filter module coupled to second port; and
a matching circuit module coupled to the high pass filter module, wherein the matching circuit module provides an impedance such that input impedance of a source of the first signal and output impedance of a destination of the first signal substantially match impedance of the first and second trace segments in the first frequency range.

14. The frequency division coupling circuit of claim 8, wherein each of the first and second segregation modules comprises:
a high pass filter module coupled to first port;
a low pass filter module coupled to second port;
a matching circuit module coupled to the high pass filter module, wherein the matching circuit module provides an impedance such that input impedance of a source of the first signal and output impedance of a destination of the first signal substantially match impedance of the first and second trace segments in the first frequency range; and
a second low pass filter coupled to the low pass filter, wherein the second low pass filter has a corner frequency greater than the second frequency range.

15. An integrated circuit (IC) comprises:
a first trace segment;
a second trace segment;
a third trace segment;
a first segregation module coupled between the first and second trace segments, wherein a first port of the first segregation module supports a high frequency signal, a second port of the first segregation module supports a power connection, and a third port of the first segregation module supports the high frequency signal and the power connection;
a second segregation module coupled between the second and third trace segments, wherein a first port of the second segregation module supports the high frequency signal, a second port of the second segregation module supports the power connection, and a third port of the second segregation module supports the high frequency signal and the power connection; and
a fourth trace proximal to the second trace, wherein the second trace and the fourth trace provide an electromagnetic wave conduit for the high frequency signal and wherein the fourth trace supports another power connection.

16. The IC of claim 15 further comprises:
a first circuit block coupled to the first and fourth traces to receive a power supply voltage and coupled to the second port of the first segregation module; and
a second circuit block coupled to the third and fourth traces to receive the power supply voltage and coupled to the second port of the second segregation module, wherein the high frequency signal is conveyed between the first and second circuit blocks via the electromagnetic wave conduit.

17. The IC of claim 15, wherein each of the first and second segregation modules comprises:
a high pass filter module coupled between the first and third ports; and
a low pass filter module coupled between the second and third ports.

18. The IC of claim 15, wherein each of the first and second segregation modules comprises:
a high pass filter module coupled between the first and third ports;
a low pass filter module coupled between the second and third ports; and
a matching circuit module coupled to the high pass filter module, wherein the matching circuit module provides an impedance such that input impedance of a source of the high frequency signal and output impedance of a destination of the high frequency signal substantially match impedance of the electromagnetic wave conduit.

19. The IC of claim 15 further comprises:
the power connection supporting a power supply voltage; and
the another power connection supporting a power supply return.

20. The IC of claim 15 further comprises:
the power connection supporting a power supply return; and
the another power connection supporting a power supply voltage.
